(19) United States
(12) Patent Application Publication
(10) Pub. No.: US 2010/0244181 A1
(43) Pub. Date: Sep. 30, 2010

(54) Filling Gaps in Integrated Circuit Fabrication

(76) Inventor: Carlo Demuro, Bresso (MI) (IT)

Correspondence Address: Trop, Pruner & Hu, P.C., 1616 S. Voss Road, Suite 750, Houston, TX, 77057-2631, US

(21) Appl. No.: 12/411,450

(22) Filed: Mar. 26, 2009

(51) Int. Cl. H01L 29/06; H01L 21/762

(52) U.S. Cl. 257/506; 438/400; 257/E21.546; 257/E29.02

(57) ABSTRACT

A gap may be filled using deposition and sputtering by forming a liner and a gap fill material in the same deposition chamber in some embodiments. The liner may be made harder than the gap fill so that the liner protects the underlying substrate when sputtering is used during the gap fill.

### BACKGROUND

This relates generally to filling gaps or trenches in semiconductor processing.

In the course of semiconductor processing, it is often desirable to form gaps or trenches. As used herein, trenches and gaps are synonymous. These gaps or trenches may then be filled with suitable materials. Filled trenches are commonly used for isolating regions on a semiconductor die, for example, via shallow trench isolation.

One issue that arises with conventional gap filling techniques is that, if the gap or trench is sufficiently narrow, the process of filling the gap causes the top of the gap to close before the bottom of the gap is completely filled. In order to overcome this problem, sputtering may be utilized during the deposition process.

However, sputtering erodes the underlying substrate. While sputtering may prevent the premature closing of the top of the gap or trench, it may cause damage to the underlying substrate as well.

### BRIEF DESCRIPTION OF THE DRAWINGS

FIG. 1 is a partial, enlarged, cross-sectional view at an early stage of manufacture according to one embodiment;

FIG. 2 is a partial, enlarged, cross-sectional view at a subsequent stage according to one embodiment;

FIG. 3 is a partial, enlarged, cross-sectional view at a subsequent stage according to one embodiment;

FIG. 4 is a partial, enlarged view at a subsequent stage according to one embodiment; and

FIG. 5 is a flow sequence for one embodiment.

### DETAILED DESCRIPTION

In accordance with some embodiments, a liner may be formed in situ within a gap or a trench, over an underlying substrate, before actually beginning the trench or gap fill process. The liner may be harder and more resistant to the sputtering, used in the course of the gap fill process, than the underlying substrate. Thus, the liner may prevent damage to the underlying substrate in some embodiments. In addition, in some embodiments, the liner may be formed in the same reactor that is used to fill the gap or trench.

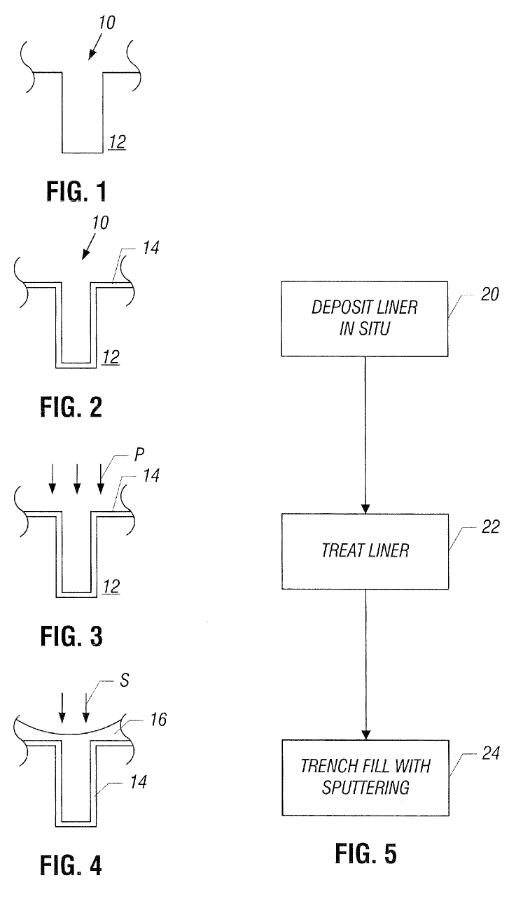

Referring to FIG. 1, a substrate 12 may have a gap or trench 10 formed therein. The substrate 12 may typically be a dielectric, such as silicon nitride. However, the substrate may be any material prone to sputtering damage. The trench 10 may have an aspect ratio, in some embodiments, such that conventional film deposition processes cause closure of the top of the gap before the bottom is completely filled.

Referring to FIG. 2, a liner 14 may be deposited within a reactor. In one embodiment, the reactor is a high density plasma (HDP) chemical vapor deposition (CVD) reactor. In some embodiments, the same reactor may also be used subsequently for gap filling. In fact, it is not necessary to remove the wafers at any time from the reactor (prior to completion of gap filling) and the entire sequence may be formed in situ within the same reactor in some embodiments.

The liner deposition may be done using relatively lower sputtering energy. For example, about 30 percent of the amount of sputtering that may be used subsequently in gap filling may be utilized for the liner 14 deposition. In addition, the high frequency radio frequency power and/or the low frequency radio frequency power may be lower in the liner deposition. In some embodiments, the high frequency radio frequency power may be about 30% less than what is used in the subsequent gap fill process and the low frequency radio frequency power may be about 40% less than what is used in the subsequent gap fill process. In addition, the oxygen flow rate in the liner 14 formation process may be two times that subsequently used for the gap fill deposition in some embodiments.

Finally, the amount of silane used may be increased, in some embodiments, when forming the liner 14. The silane flow during liner deposition may be more than seven times the silane flow in the subsequent gap filling process in one embodiment. The silane to oxygen ratio may be 1.6 to 1 in the liner 14 deposition, while the gap fill silane to oxygen ratio may be 1 to 2.4 in some embodiments. The liner may be about 280 Angstroms in some embodiments.

While a single layer liner is described above, the liner may be formed of multiple layers in some embodiments. Although the layer is described as a dielectric layer and, particularly, an oxide layer, other materials may also be used for the liner, in some cases. In addition, in some cases, the liner may be grown rather than being deposited.

After liner formation, the liner may be treated by exposing it to a plasma P, as shown in FIG. 3. The plasma treatment results in hardening the liner, making it more resistant upon exposure to sputtering used in the subsequent gap fill process. The plasma treatment may be done in situ in the same reactor. For example, the plasma treatment may use helium and oxygen. In some cases, plasma treatment may heat the wafer, causing diffusion of implanted or bombarded species. In situ thermal treatment may involve temperatures at about 350° C. for about twenty seconds, in some embodiments.

Then, as shown in FIG. 4, the gap fill process S begins. The gap fill process may be accompanied with sputtering so that the gap is completely filled from top to bottom without the formation of voids that result when the top of the gap is closed off prematurely as a result of the re-sputtering process and oxide deposition rate dependence on surface slope. The gap fill may use high density plasma oxide similar to the oxide used for the liner 14, in some embodiments, with the changes described above with respect to sputtering, high frequency power, low frequency power, silane composition, and oxygen composition, in some embodiments.

By making the liner relatively hard, the liner 14 may resist the sputtering that would otherwise damage the underlying substrate 12. The hardness may be the result of in situ thermal treatment, as well as the plasma treatment, in some embodiments.

Then, as shown in FIG. 4, the trenches are filled using deposition with sputtering using a HDPCVD in one embodiment. The sputtering does not damage the substrate 12 because of the protection afforded by the previously formed liner 14.

Thus, referring to FIG. 5, a sequence of operations involves initially depositing the liner in situ within a reactor, as indicated in block 20. The liner may than be treated, as indicated in block 22, with one or more plasma and/or thermal treatments in order to make the liner more resistant to the subsequent sputtering exposure. The liner may be formed of basically the same material as will be used for gap filling, with slightly modified properties compared to the subsequent gap fill, in some embodiments. Oxide and silane compositions may be different in some cases, but the same reactor may be used for both deposition processes, in some embodiments.

Finally, the gap or trench is filled (block 24) with a deposition and sputtering process to prevent the gap or trench from closing prematurely. During this process, the substrate is protected by the liner 14.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a liner in a gap formed in a substrate, to protect the substrate from sputtering; and
filling the gap, with the liner in place, using deposition and sputtering.

2. The method of claim 1 wherein forming a liner includes hardening the liner.

3. The method of claim 2 wherein hardening the liner includes exposing the liner to a plasma.

4. The method of claim 3 wherein hardening the liner includes exposing the liner to inert plasma.

5. The method of claim 2 wherein hardening the liner includes heating the liner.

6. The method of claim 1 including forming the liner and filling the gap in the same deposition tool.

7. The method of claim 6 including filling the gap and forming the liner in a high density plasma oxide deposition tool.

8. The method of claim 6 including using deposition and sputtering to form said liner and to fill said gap and using less sputtering to form said liner than is used to fill the gap.

9. The method of claim 6 including using silane and oxygen to form said liner and to fill said gap and using more silane than oxygen to form the liner and using more oxygen than silane to fill the gap.

10. The method of claim 6 including reducing at least one of the high frequency and low frequency power when forming the liner relative to filling the gap.

11. An apparatus comprising:
a substrate including a plurality of gaps;
a liner in said gap; and
a gap fill in said gap over said liner, said liner being harder than said gap fill.

12. The apparatus of claim 11 wherein said gap fill and said liner are both oxide.

13. The apparatus of claim 12 wherein the silane to oxygen ratio of said liner is higher than said silane to oxygen ratio of said gap fill.

14. The apparatus of claim 11 wherein said liner and said gap fill are formed of the same material.

15. The apparatus of claim 14 wherein said liner and said gap fill are oxide.

16. The apparatus of claim 15 wherein said liner and said gap fill are high density plasma oxide.

17. A method comprising:
forming a liner in gap;
filling said gap with a gap fill with said liner in place, using deposition and sputtering, and making said liner harder than the gap fill; and
using the same deposition tool to form said liner and said gap fill.

18. The method of claim 17 including forming said liner and said gap fill of the same material.

19. The method of claim 18 including hardening the liner using one of heat and plasma treatment.

20. The method of claim 17 including forming said liner and said gap fill of oxide.
